(19) United States
(12) Patent Application Publication
(10) Pub. No.: US 2026/0186055 A1
(43) Pub. Date: Jul. 2, 2026

(54) TEST NETWORK RESET CIRCUITS

(71) Applicant: Intel Corporation, Santa Clara, CA (US)

(72) Inventors: Kok Wee GUN, Bayan Lepas (MY); Huah Yuah TAN, Bayan Lepas (MY)

(21) Appl. No.: 19/002,965

(22) Filed: Dec. 27, 2024

(51) Int. Cl. G01R 31/3185; G01R 31/3177

(52) U.S. Cl. CPC G01R 31/318555; G01R 31/3177; G01R 31/318558

(57) ABSTRACT

Disclosed are reset circuitry for test paths in an integrated circuit test network. The reset circuitry may include a SIB (section insertion bit) circuit with a reset register to facilitate reliable reset of test path registers associated with the SIB circuit.

### TECHNICAL FIELD

Embodiments relate to the field of semiconductors and more particularly, to the field of semiconductor test circuits.

### BRIEF DESCRIPTION OF THE DRAWINGS

The disclosure may best be understood by referring to the following description and accompanying drawings that are used to illustrate embodiments. In the drawings:

FIG. 1A is a block diagram showing a test network hierarchy for accessing iJTAG test devices.

FIG. 1B is a block diagram showing how IP test structures may be accessed in a test access network in accordance with some embodiments.

FIG. 1C is a diagram showing the network of FIG. 1B with an IP functional circuit occupying multiple power domains.

FIG. 1D is a timing diagram illustrating the exemplary issue of FIG. 1C.

FIG. 2A is a diagram showing a multi-level SIB circuit in accordance with some embodiments.

FIG. 2B is a diagram showing an IC with an iJTAG test network including SIB circuits in accordance with some embodiments.

FIG. 3A is a flow diagram showing a routine for controlling a TDR with a multi-level SIB circuit in accordance with some embodiments.

FIG. 3B is a flow diagram showing a routine for accessing and running a test in a TDR test path segment in accordance with some embodiments.

FIGS. 4A and 4B are diagrams illustrating how multi-power domain TDR reset issues may be avoided using a SIB circuit in accordance with some embodiments.

FIG. 5 illustrates an example computing system with ICs with test networks in accordance with some embodiments.

FIG. 6 illustrates a block diagram of an example processor and/or SoC that may have one or more cores and an integrated memory controller with test circuits in accordance with some embodiments.

FIG. 7 is a block diagram illustrating a computing system configured to implement one or more aspects of the examples described herein.

### DETAILED DESCRIPTION

IEEE P1687, also known as iJTAG (Internal Joint Test Action Group), is a standard developed to enhance the integration and testing of embedded instruments within semiconductor devices. It builds upon the existing IEEE 1149.1 (JTAG) standard, providing a more flexible and efficient framework for accessing various internal components of integrated circuits (ICs).

IJTAG facilitates the plug-and-play integration of intellectual property (IP) blocks within large integrated circuits (ICs) such as systems-on-chip (SoCs). This standard allows for a uniform method to describe and access chip internal IP blocks, enabling easier reuse and integration of these components in designs.

Among other things, IJTAG defines two compute languages, ICL and PDL, for accessing and controlling tests on functional circuits in IP blocks. ICL (Instrument Connectivity Language) describes the hierarchical connectivity of the scan network between the JTAG Test Access Port (TAP) and the embedded test instrument circuits. PDL (Procedural Description Language) outlines the patterns used to interact with these instruments, allowing for standardized communication protocols.

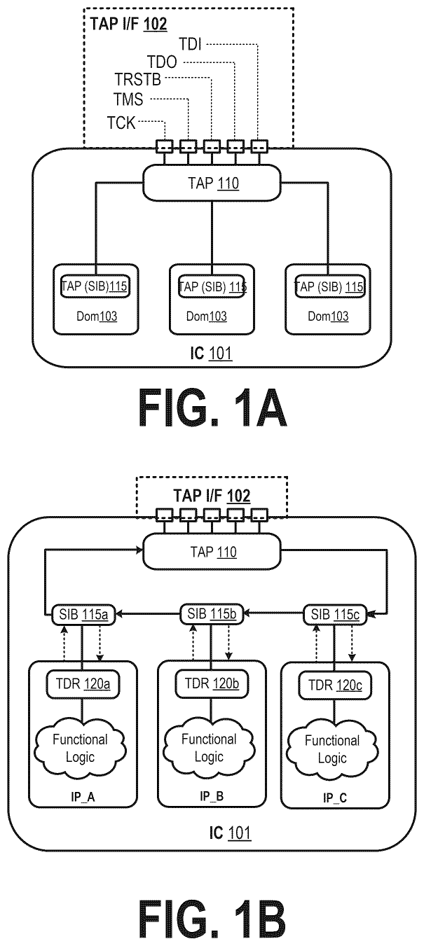

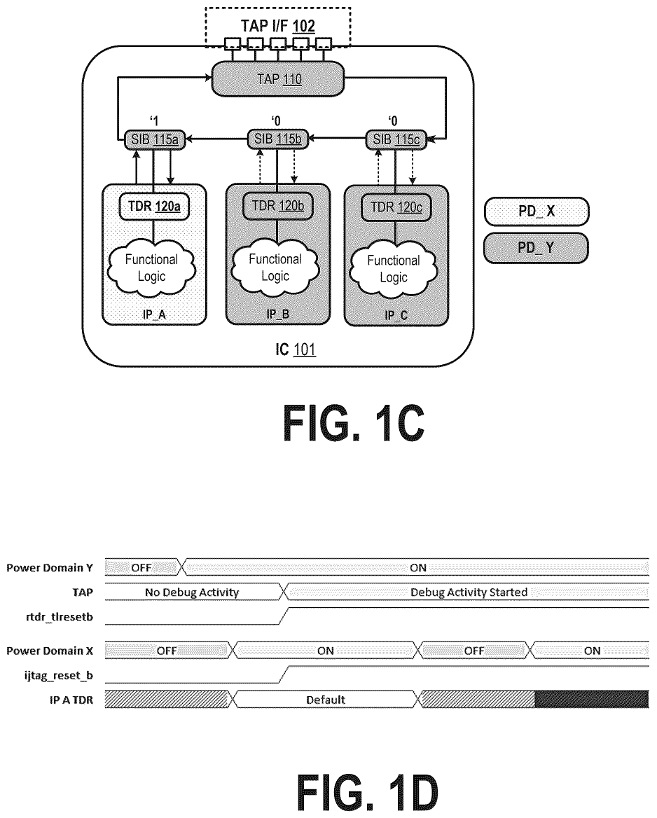

FIG. 1A is a block diagram showing a test network hierarchy for accessing and using iJTAG test devices in an IC 101. The IC 101 includes a plurality of domains 103 (e.g., IP circuit blocks, cores, etc.) that include test component, or instrument, circuits for testing the domain functional circuitry. The test network includes a primary (or main) test access port (TAP) 110 and a plurality of sub TAPs 115 to access the separate domains 103. (Note that the terms: SIB or SIB circuit are used interchangeably with “sub TAP” since SIB functionality, as discussed further below, is a focus of sub TAP operation for this disclosure.)

The test network architecture is facilitated by the IEEE P1687 standard (iJTAG), which allows for hierarchical access to embedded test instrument circuits within an IC architecture. The primary TAP 110 serves as the top-level access point for the IC, enabling communication with various embedded circuits and other components. As is illustrated, each sub-TAP can be associated with specific domains 103 within the IC 101. These sub-TAPs 115 can communicate with the main TAP 110, allowing for a structured and organized way to manage test access across different levels of the IC.

The main TAP 110 has a TAP interface 102 to facilitate control and communication between the test network and an external test control system (not shown). the interface 102 includes a variety of access ports (e.g., single bit or other) including a TCK (test clock) input, a TDI (test data input for injecting control data and test patterns), a TMS (test mode select) input to control state machine logic to access a desired domain, a TRSTB (test reset B) input for resetting the state machine control logic, and a TDO (test data output) to read test status information and other results.

The TAP 110 controls the overall scan paths for the test network and can selectively activate or bypass sub TAPs (or SIB circuits) 115 using Segment Interconnect Bits (SIBs). This enables efficient management of test data flow and access to different parts of the IC without requiring physical reconfiguration of connections.

FIG. 1B is a block diagram showing how IP test structures may be accessed in a test access network in accordance with some embodiments. The test network includes the main TAP 110 coupled to a plurality of SIB circuits (or sub TAPs) 115a-115c. The SIB circuits 115 facilitate controllable access to associated test circuits in IP domains (e.g., IP_A, IP_B, IP_C) through test data registers (120a-120c). (Note that while only 3 IP domains are shown for ease of presentation, typical ICs can include hundreds, if not more, IP blocks, with associated test structures.)

The SIBs are coupled together with the main TAP 110 through a network path, illustrated using the solid arrowed lines. If certain IP test circuits are to be accessed, an appropriate sequence of bits is driven through this path to enable (or “open”) the SIB circuit(s) 115 to access their associated TDR(s) 120. Selecting’ a certain SIB (e.g., writing into it a ‘1) activates the test data register (TDR) 120 on that segment. Conversely, de-selecting’ a SIB (e.g., writing into it a ‘0) will render the test instruments on that segment inaccessible. The dashed arrowed lines indicate the potential IP test circuit paths that may be opened, depending on the state of their associated SIB.

A problem arises with the ever-growing numbers of different power gating levels implemented in ICs such as SOCs, CPUs, graphics processors and even FPGAs (field programmable gate arrays). All of the different IP blocks that can be used in an IC with different power domains need to be connected to appropriate TAP paths and/or networks according to their power domain to ensure the correct functionality of the TAPs without functional circuit or system corruption. A simple example to illustrate this issue is shown in FIG. 1C.

FIG. 1C is a diagram showing the network of FIG. 1B with an IP functional circuit (IP_A functional logic) occupying multiple power domains. With this example, IP-A's functional logic is part of power domain X, which itself is a sub-domain within a larger power domain Y. The reset signal for resetting, or initializing, the IP_A TDR, as well as the TDRs for the other IPs, is derived based on a power good indicator from the Y power domain. Due to the wrong power good indicator, the IP_A TDR (120a) fails to reset, or re-initialize, because there has been no such indication from power domain Y, which unlike power domain X, has not powered down and restarted. So tests running through the uninitialized TDR for IP_A might be corrupted or otherwise cause the system to hang as the uninitialized TDR test values will propagate into the functional logic being tested.

FIG. 1D is a timing diagram that further illustrates this issue. During On/Off/On states of the X power domain, with the wrong power good connection to the IP A TDR (from PD_Y and not PD_X), the IP_A TDR register bits are not properly reset/initialized and have unknown states that can cause the functional system to fail.

There have been several different solutions to address this issue. For example, in some approaches, the IP SIB/TDRs are connected to associated parent TAPs with the same power domain. With other approaches, the reset to IP SIB (TAP)/TDR with the IP's power domain indicator is qualified to check if the parent TAP is in a different power domain so as to be aware of possible problems from test functions running without appropriate functional circuit resets. Unfortunately, both of these approaches can be prone to errors and also can consume excessive qualification and validation resources.

Accordingly, new approaches are desired. In some embodiments, a SIB enhancement hold-in-reset feature that may be used with multi power domain IP TDRs is provided. In some embodiments, an added layer of SIB circuit may be utilized for the purpose of Power/Reset to the IP TDRs. Among other things, this can de-couple the power domain dependency between iJTAG network chains (or paths) and associated IP TDRs. The added SIB circuit layer can act as an extra guard to prevent possible system corruption upon an exit from a low power state due to an uninitialized TDR caused by an improper power domain indicator connection.

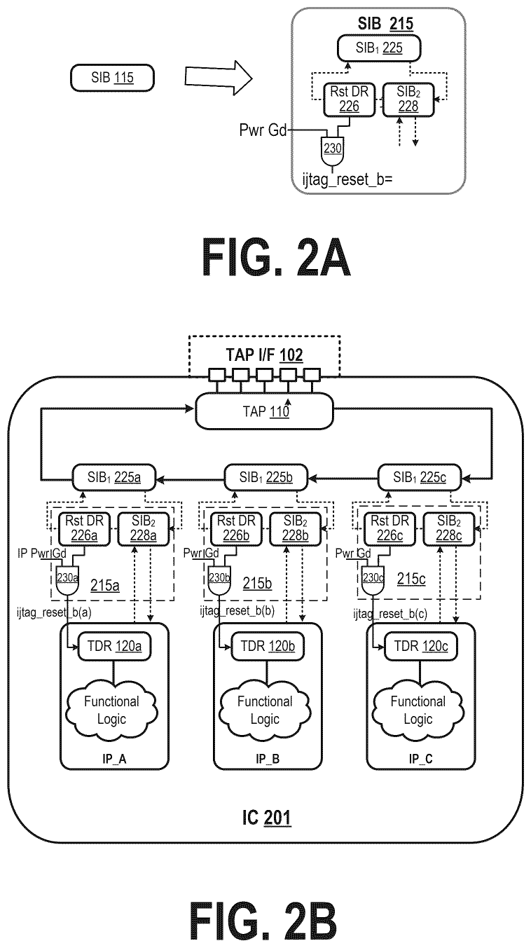

With reference to FIGS. 2A-2B, FIG. 2A shows a multi-level SIB circuit 215, and FIG. 2B shows an IC 201 with an iJTAG test network including SIB circuits 215, in accordance with some embodiments. SIB circuit 215 includes switch (e.g., multiplexer) and/or other path access circuitry (not shown) controlled through a first level SIB register circuit 225 (SIB₁), a second level SIB register circuit 228 (SIB₂), a reset data register circuit (Rst DR), and an And gate 230, coupled together as shown. The first level SIB circuit, as with conventional SIB circuits, opens its associated test path if its SIB (section insertion bit) is asserted (e.g., ‘1). If so, then if the second level SIB circuit bit is also asserted, the path associated with the second level SIB is also opened. (Note that this second level SIB switch/register circuit can facilitate multiple different paths coupled from the first level SIB switch/register circuit. However, in some embodiments, when only one path is coupled to the first level SIB, the second level SIB circuit may be omitted.)

The Rst DR register is used to ensure that the associated TDR has been reset and will be initialized upon the opening and use of the test TDR test path. When a test is to be run, a “1 is written into the Rst DR register to “clear” the reset state of the TDR. In some embodiments, the SIB circuit 215 is configured so that before the TDR is accessed, the reset DR 226 holds the TDR in a reset state. In order to access the TDR, a user needs to write a ‘1 into the reset DR in order to bring it out of reset. With this hold-in-reset logic, the TDR is forced to properly initialize upon power up and avoid possible corruption to functional logic in a case of an incorrect reset connection.

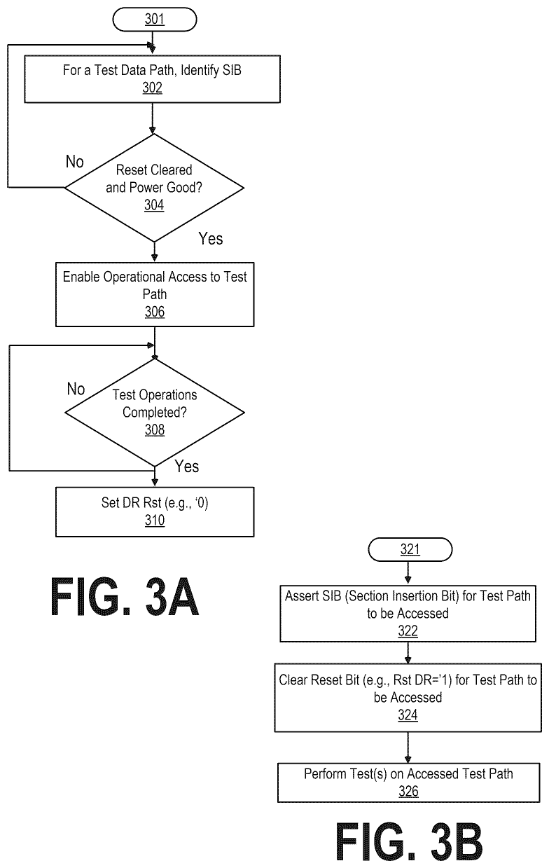

FIG. 3A is a flow diagram showing a routine for controlling a TDR with a multi-level SIB circuit in accordance with some embodiments. This routine may be implemented with SIB circuit 215, alone or in cooperation with any suitable logic (e.g., state machine, circuits, firmware, etc.). At 302, for a test data path being accessed, the routine identifies the state of a SIB to provide access to the data path. At 304, it checks/confirms that a reset clear bit is in an appropriate state (e.g., Rst DR=‘1), and it also confirms that a relevant power good indicator is asserted? If both conditions are satisfied, then at 306, it facilitates operational Access to the test path through a relevant TDR. Otherwise, from 304, it loops back to the beginning until the conditions are satisfied.

At 308, it determines if test operations have completed. If not, it loops upon itself until the test operation has finished. When it is done, the routine goes to 310 and causes the reset DR to be set in a reset state (e.g., Rst DR=‘0).

FIG. 3B is a flow diagram showing a routine 321 for accessing and running a test in a TDR test path segment in accordance with some embodiments. At 322, a SIB (section insertion Bit) is asserted for the test path to be accessed. At 324, a SIB circuit reset (e.g., Rst DR) for the test path is cleared (e.g., ‘1 written to reset register). At 326, the test(s) on the accessed test path are performed.

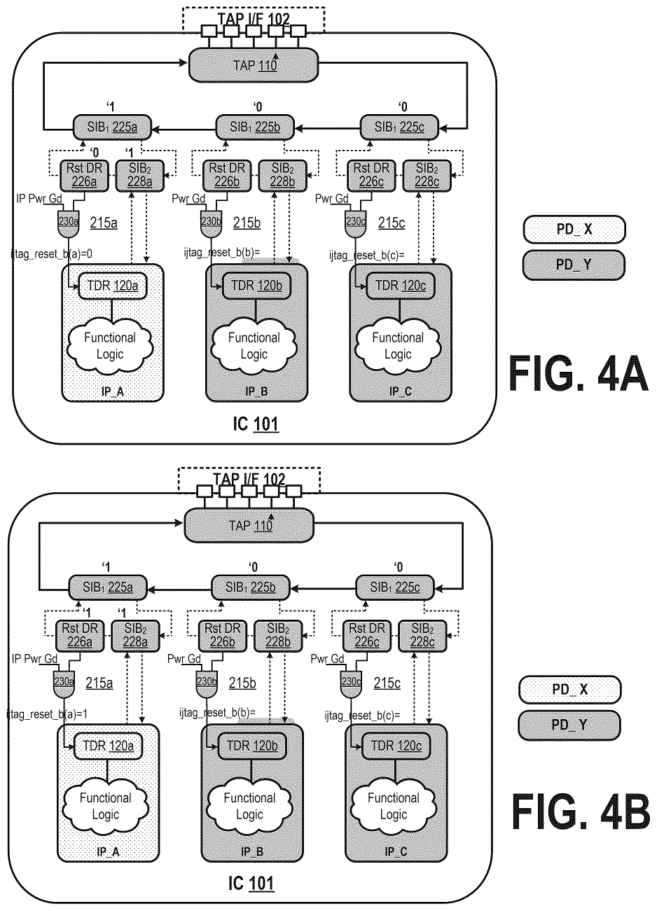

FIGS. 4A and 4B are diagrams illustrating how multi-power domain TDR reset issues may be avoided using a SIB circuit in accordance with some embodiments. FIG. 4A shows the test network in an initial state. This corresponds to PD_Y powering up and booting. Here, PD_Y is On and PD_X is Off. During initial boot, power domain Y will be powered up first, and the rest signal (rtdr_tlresetb) for Y will transition to ‘1. Without the DR reset feature, When Power domain X is powered up, the TDR for IP_A may not get initialized properly because the previously associated reset signal (ijtag_reset_b) for Y would be ‘1.

However, with the SIB hold-in-reset logic, the problem is avoided. When power domain X is powered up, the TDR for IP_A will get initialized properly because the DR reset register (Rst DR) 226a is defaulted to a reset (‘0) state. Therefore, the reset signal (ijtag_reset_b) for the IP_A TDR is ‘0 here, which ensures that the TDR is properly initialized, even though it may have an incorrect power good connection.

FIG. 4B shows the test network in a full-On mode with both domains being powered. Before a user accesses the IP_A TDR for testing, it needs to program the Rst DR to ‘1 in order to bring the IP_A TDR out of reset, which causes the TDR states to be initialized. Once done, the user can access the TDR. Now, when PD_Y is On and PD_X goes off (e.g., during low power debug, PD_X might get turned off while PD Y remains On), the circuitry, in some embodiments, will cause Rst DR to come up with a ‘0, ensuring that the TDR resets when a user accesses it with the “1 write to the Rst DR register. In some embodiments, circuitry may not be available to force the reset register (Rst DR) to come up in a ‘0 state. With such embodiments and with a SIB circuit such as SIB circuit 215, the user can initially write into the reset register a ‘0, followed by a ‘1, and achieve the same reset assurance.

Note that in this disclosure, a JTAG TAP (Test Access Port) is primarily used as an example for accessing the test network. However, any suitable interface may be used. The IEEE P1687.1 specification extends the capabilities of iJTAG by allowing it to interface with a broad range of device controllers beyond a traditional JTAG TAP. This includes interfaces like I2C, SPI, and others, thereby broadening the scope of devices that can utilize iJTAG networks.

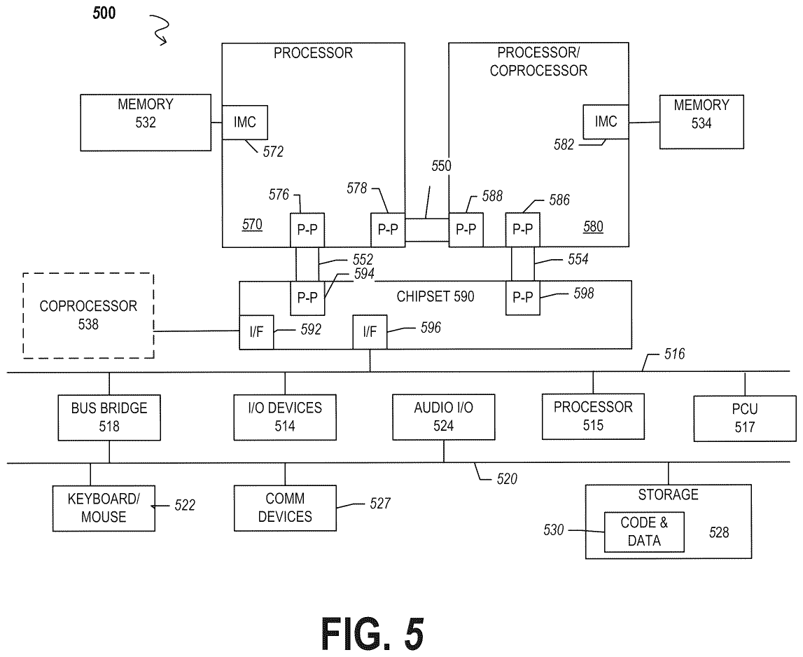

FIG. 5 illustrates an example computing system that may have ICs with test networks in accordance with some embodiments. Multiprocessor system 500 is an interfaced system and includes a plurality of processors including a first processor 570 and a second processor 580 coupled via an interface 550 such as a point-to-point (P-P) interconnect, a fabric, and/or bus. In some examples, the first processor 570 and the second processor 580 are homogeneous. In some examples, first processor 570 and the second processor 580 are heterogenous. Though the example system 500 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 570 and 580 are shown including integrated memory controller (IMC) circuitry 572 and 582, respectively. Processor 570 also includes interface circuits 576 and 578, along with core sets. Similarly, second processor 580 includes interface circuits 586 and 588, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 570, 580 may exchange information via the interface 550 using interface circuits 578, 588. IMCs 572 and 582 couple the processors 570, 580 to respective memories, namely a memory 532 and a memory 534, which may be portions of main memory locally attached to the respective processors.

Processors 570, 580 may each exchange information with a network interface (NW I/F) 590 via individual interfaces 552, 554 using interface circuits 576, 594, 586, 598. The network interface 590 (e.g., one or more of an interconnect, bus, and/or fabric, and in some examples is a chipset) may optionally exchange information with a coprocessor 538 via an interface circuit 592. In some examples, the coprocessor 538 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 570, 580 or outside of both processors, yet connected with the processors via an interface such as P-P interconnect, such that either or both processors' local cache information may be stored in the shared cache if a processor is placed into a low power mode.

Network interface 590 may be coupled to a first interface 516 via interface circuit 596. In some examples, first interface 516 may be an interface such as a Peripheral Component Interconnect (PCI) interconnect, a PCI Express interconnect, or another I/O interconnect. In some examples, first interface 516 is coupled to a power control unit (PCU) 517, which may include circuitry, software, and/or firmware to perform power management operations with regard to the processors 570, 580 and/or co-processor 538. PCU 517 provides control information to one or more voltage regulators (not shown) to cause the voltage regulator(s) to generate the appropriate regulated voltage(s). PCU 517 also provides control information to control the operating voltage generated. In various examples, PCU 517 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 517 is illustrated as being present as logic separate from the processor 570 and/or processor 580. In other cases, PCU 517 may execute on a given one or more of cores (not shown) of processor 570 or 580. In some cases, PCU 517 may be implemented as a microcontroller (dedicated or general-purpose) or other control logic configured to execute its own dedicated power management code, sometimes referred to as P-code. In yet other examples, power management operations to be performed by PCU 517 may be implemented externally to a processor, such as by way of a separate power management integrated circuit (PMIC) or another component external to the processor. In yet other examples, power management operations to be performed by PCU 517 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 514 may be coupled to first interface 516, along with a bus bridge 518 which couples first interface 516 to a second interface 520. In some examples, one or more additional processor(s) 515, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 516. In some examples, second interface 520 may be a low pin count (LPC) interface. Various devices may be coupled to second interface 520 including, for example, a keyboard and/or mouse 522, communication devices 527 and storage circuitry 528. Storage circuitry 528 may be one or more non-transitory machine-readable storage media as described below, such as a disk drive or other mass storage device which may include instructions/code and data 530 and may implement the storage in some examples. Further, an audio I/O 524 may be coupled to second interface 520. Note that other architectures than the point-to-point architecture described above are possible. For example, instead of the point-to-point architecture, a system such as multiprocessor system 500 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

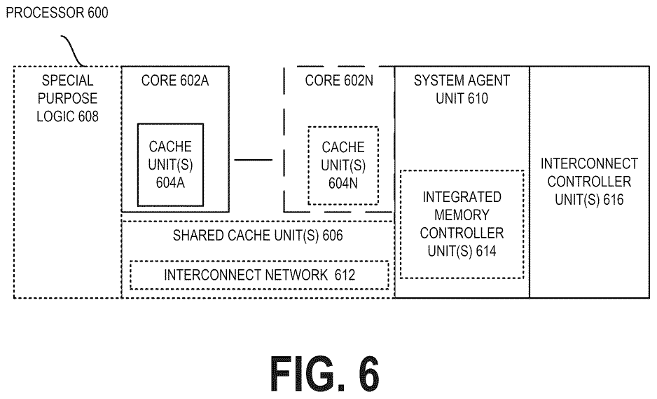

FIG. 6 illustrates a block diagram of an example processor and/or SoC 600 that may have one or more cores and an integrated memory controller. The solid lined boxes illustrate a processor and/or SoC 600 with a single core 602(A), system agent unit circuitry 610, and a set of one or more interface controller unit(s) circuitry 616, while the optional addition of the dashed lined boxes illustrates an alternative processor and/or SoC 600 with multiple cores 602(A)-(N), a set of one or more integrated memory controller unit(s) circuitry 614 in the system agent unit circuitry 610, and special purpose logic 608, as well as a set of one or more interface controller unit(s) circuitry 616. Note that the processor and/or SoC 600 may be one of the processors 570 or 580, or co-processor 538 or 515 of FIG. 5.

Thus, different implementations of the processor and/or SoC 600 may include: 1) a CPU with the special purpose logic 608 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like(which may include one or more cores, not shown), and the cores 602(A)-(N) being one or more general purpose cores (e.g., general purpose in-order cores, general purpose out-of-order cores, or a combination of the two); 2) a co-processor with the cores 602(A)-(N) being a large number of special purpose cores intended primarily for graphics and/or scientific (throughput); and 3) a co-processor with the cores 602(A)-(N) being a large number of general purpose in-order cores. Thus, the processor and/or SoC 600 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 600 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 604(A)-(N) within the cores 602(A)-(N), a set of one or more shared cache unit(s) circuitry 606, and external memory (not shown) coupled to the set of integrated memory controller unit(s) circuitry 614. The set of one or more shared cache unit(s) circuitry 606 may include one or more mid-level caches, such as level 2(L 2 ), level 3(L 3 ), level 4(L 4 ), or other levels of cache, such as a last level cache (LLC), and/or combinations thereof. While in some examples interface network circuitry 612 (e.g., a ring interconnect) interfaces the special purpose logic 608 (e.g., integrated graphics logic), the set of shared cache unit(s) circuitry 606, and the system agent unit circuitry 610, alternative examples use any number of well-known techniques for interfacing such units. In some examples, coherency is maintained between one or more of the shared cache unit(s) circuitry 606 and cores 602(A)-(N). In some examples, interface controller unit(s) circuitry 616 couple the cores 602(A)-(N) to one or more other devices 618 such as one or more I/O devices, storage, one or more communication devices (e.g., wireless networking, wired networking, etc.), etc.

In some examples, one or more of the cores 602(A)-(N) are capable of multi-threading. The system agent unit circuitry 610 includes those components coordinating and operating cores 602(A)-(N). The system agent unit circuitry 610 may include, for example, power control unit (PCU) circuitry and/or display unit circuitry (not shown). The PCU may be or may include logic and components needed for regulating the power state of the cores 602(A)-(N) and/or the special purpose logic 608 (e.g., integrated graphics logic). The display unit circuitry is for driving one or more externally connected displays.

The cores 602(A)-(N) may be homogenous in terms of instruction set architecture (ISA). Alternatively, the cores 602(A)-(N) may be heterogeneous in terms of ISA; that is, a subset of the cores 602(A)-(N) may be capable of executing an ISA, while other cores may be capable of executing only a subset of that ISA or another ISA.

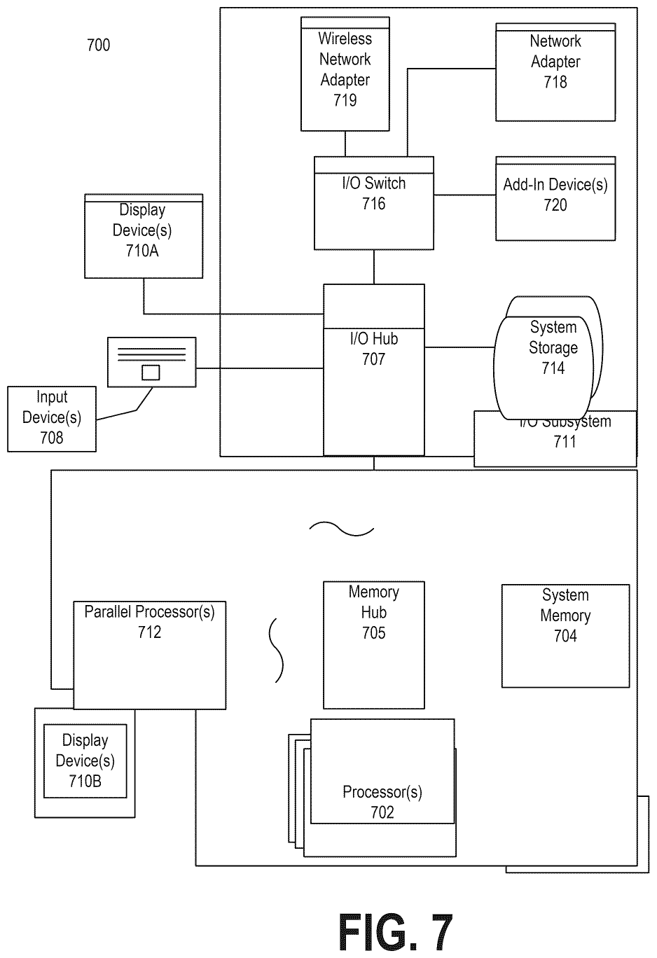

FIG. 7 is a block diagram illustrating a computing system 700 configured to implement one or more aspects of the examples described herein. The computing system 700 includes a processing subsystem 701 having one or more processor(s) 702 and a system memory 704 communicating via an interconnection path that may include a memory hub 705. The memory hub 705 may be a separate component within a chipset component or may be integrated within the one or more processor(s) 702. The memory hub 705 couples with an I/O subsystem 711 via a communication link 706. The I/O subsystem 711 includes an I/O hub 707 that can enable the computing system 700 to receive input from one or more input device(s) 708. Additionally, the I/O hub 707 can enable a display controller, which may be included in the one or more processor(s) 702, to provide outputs to one or more display device(s) 710A. In some examples the one or more display device(s) 710A coupled with the I/O hub 707 can include a local, internal, or embedded display device.

The processing subsystem 701, for example, includes one or more parallel processor(s) 712 coupled to memory hub 705 via a bus or communication link 713. The communication link 713 may be one of any number of standards-based communication link technologies or protocols, such as, but not limited to PCI Express, or may be a vendor specific communications interface or communications fabric. The one or more parallel processor(s) 712 may form a computationally focused parallel or vector processing system that can include a large number of processing cores and/or processing clusters, such as a many integrated core (MIC) processor. For example, the one or more parallel processor(s) 712 form a graphics processing subsystem that can output pixels to one of the one or more display device(s) 710A coupled via the I/O hub 707. The one or more parallel processor(s) 712 can also include a display controller and display interface (not shown) to enable a direct connection to one or more display device(s) 710B.

Within the I/O subsystem 711, a system storage unit 714 can connect to the I/O hub 707 to provide a storage mechanism for the computing system 700. An I/O switch 716 can be used to provide an interface mechanism to enable connections between the I/O hub 707 and other components, such as a network adapter 718 and/or wireless network adapter 719 that may be integrated into the platform, and various other devices that can be added via one or more add-in device(s) 720. The add-in device(s) 720 may also include, for example, one or more external graphics processor devices, graphics cards, and/or compute accelerators. The network adapter 718 can be an Ethernet adapter or another wired network adapter. The wireless network adapter 719 can include one or more of a Wi-Fi, Bluetooth, near field communication (NFC), or other network device that includes one or more wireless radios.

The computing system 700 can include other components not explicitly shown, including USB or other port connections, optical storage drives, video capture devices, and the like, which may also be connected to the I/O hub 707. Communication paths interconnecting the various components in FIG. 7 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL. mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 712 may incorporate circuitry optimized for graphics and video processing, including, for example, video output circuitry, and constitutes a graphics processing unit (GPU). Alternatively or additionally, the one or more parallel processor(s) 712 can incorporate circuitry optimized for general purpose processing, while preserving the underlying computational architecture, described in greater detail herein. Components of the computing system 700 may be integrated with one or more other system elements on a single integrated circuit. For example, the one or more parallel processor(s) 712, memory hub 705, processor(s) 702, and I/O hub 707 can be integrated into a system on chip (SoC) integrated circuit. Alternatively, the components of the computing system 700 can be integrated into a single package to form a system in package (SIP) configuration. In some examples at least a portion of the components of the computing system 700 can be integrated into a multi-chip module (MCM), which can be interconnected with other multi-chip modules into a modular computing system.

It will be appreciated that the computing system 700 shown herein is illustrative and that variations and modifications are possible. The connection topology, including the number and arrangement of bridges, the number of processor(s) 702, and the number of parallel processor(s) 712, may be modified as desired. For instance, system memory 704 can be connected to the processor(s) 702 directly rather than through a bridge, while other devices communicate with system memory 704 via the memory hub 705 and the processor(s) 702. In other alternative topologies, the parallel processor(s) 712 are connected to the I/O hub 707 or directly to one of the one or more processor(s) 702, rather than to the memory hub 705. In other examples, the I/O hub 707 and memory hub 705 may be integrated into a single chip. It is also possible that two or more sets of processor(s) 702 are attached via multiple sockets, which can couple with two or more instances of the parallel processor(s) 712.

Some of the particular components shown herein are optional and may not be included in all implementations of the computing system 700. For example, any number of add-in cards or peripherals may be supported, or some components may be eliminated. Furthermore, some architectures may use different terminology for components similar to those illustrated in FIG. 7. For example, the memory hub 705 may be referred to as a Northbridge in some architectures, while the I/O hub 707 may be referred to as a Southbridge.

Illustrative examples of the technologies disclosed herein are provided below. An embodiment of the technologies may include any one or more, and any compatible combination of, the examples described below.

Example 1 is an apparatus that includes a test access interface and at least one SIB circuit. The test access interface is for a test network in an integrated circuit (IC). The at least one SIB (section insert bit) circuit is coupled to the interface. The SIB circuit includes a first SIB circuit access register to provide access to a test path including a test data register (TDR), and a reset register coupled to the first SIB access register and to the TDR to control a reset state of the TDR based on a value from the first SIB access register.

Example 2 includes the subject matter of example 1, and wherein the SIB circuit includes a logic gate with a first input coupled to the reset register and a second input coupled to a power indicator node.

Example 3 includes the subject matter of any of examples 1-2, and wherein the logic gate includes an output coupled to the TDR to control the reset state of the TDR.

Example 4 includes the subject matter of any of examples 1-3, and wherein the logic gate is to perform a logical AND operation.

Example 5 includes the subject matter of any of examples 1-4, and wherein the SIB circuit includes a second SIB circuit access register coupled between the first SIB circuit access register and the reset register to provide access to the reset register.

Example 6 includes the subject matter of any of examples 1-5, and wherein the second SIB circuit access register is coupled between the first SIB circuit access register and the TDR to provide access to the TDR.

Example 7 includes the subject matter of any of examples 1-6, and wherein the test access interface is a test access port (TAP).

Example 8 includes the subject matter of any of examples 1-7, and wherein the at least one SIB circuit includes a first switch to couple the test access interface to the TDR based on a state of the first SIB circuit access register.

Example 9 includes the subject matter of any of examples 1-8, and wherein the SIB circuit includes a second SIB circuit access register coupled between the first SIB circuit access register and the reset register to provide access to the TDR from the first switch.

Example 10 includes the subject matter of any of examples 1-9, and wherein the at least one SIB circuit includes a second switch to couple the first switch to the TDR based on a state of the second SIB circuit access register.

Example 11 includes the subject matter of any of examples 1-10, and wherein the test network is in conformance with an IEEE iJTAG standard.

Example 12 is an apparatus that includes a test controller configured to be coupled with a test access interface of a test network in an integrated circuit (IC). It also includes a memory including instructions that when executed by the controller cause a test apparatus to write a first bit into a first SIB circuit access register to provide access to a test path with a test data register (TDR), and to write a second bit into a reset register coupled to the first SIB access register and to the TDR to control the TDR to come out of a reset state.

Example 13 includes the subject matter of example 12, and wherein the test apparatus is to write a third bit into the reset register prior to writing the second bit, the third bit to cause the TDR to go into the reset state.

Example 14 includes the subject matter of any of examples 12-13, and wherein the test apparatus is to write a third bit into a second SIB circuit access register to provide access to the TDR from the first circuit access register.

Example 15 is a computer system that includes a processor apparatus and a memory. The processor apparatus includes a test access interface for a test network in an integrated circuit (IC). It also includes at least one SIB (section insert bit) circuit coupled to the interface, the SIB circuit including: (i) a first SIB circuit access register to provide access to a test path including a test data register (TDR), and (ii) a reset register coupled to the first SIB access register and to the TDR to control a reset state of the TDR based on a value from the first SIB access register. The memory circuit is coupled to the processor apparatus.

Example 16 includes the subject matter of example 15, and wherein the SIB circuit includes a logic gate with a first input coupled to the reset register and a second input coupled to a power indicator node.

Example 17 includes the subject matter of any of examples 15-16, and wherein the logic gate includes an output coupled to the TDR to control the reset state of the TDR.

Example 18 includes the subject matter of any of examples 15-17, and wherein the logic gate is to perform a logical AND operation.

Example 19 includes the subject matter of any of examples 15-18, and wherein the SIB circuit includes a second SIB circuit access register coupled between the first SIB circuit access register and the reset register to provide access to the reset register.

Example 20 includes the subject matter of any of examples 15-19, and wherein the second SIB circuit access register is coupled between the first SIB circuit access register and the TDR to provide access to the TDR.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors.

In the drawings of the embodiments, signals are represented with lines. Some lines may appear different from others, for example, thicker or hatched, to distinguish from other depicted signals for ease of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a test access interface for a test network in an integrated circuit (IC); and
at least one SIB (section insert bit) circuit coupled to the interface, the SIB circuit including:
a first SIB circuit access register to provide access to a test path including a test data register (TDR), and
a reset register coupled to the first SIB access register and to the TDR to control a reset state of the TDR based on a value from the first SIB access register.

2. The apparatus of claim 1, wherein the SIB circuit includes a logic gate with a first input coupled to the reset register and a second input coupled to a power indicator node.

3. The apparatus of claim 2, wherein the logic gate includes an output coupled to the TDR to control the reset state of the TDR.

4. The apparatus of claim 2, wherein the logic gate is to perform a logical AND operation.

5. The apparatus of claim 1, wherein the SIB circuit includes a second SIB circuit access register coupled between the first SIB circuit access register and the reset register to provide access to the reset register.

6. The apparatus of claim 5, wherein the second SIB circuit access register is coupled between the first SIB circuit access register and the TDR to provide access to the TDR.

7. The apparatus of claim 1, wherein the test access interface is a test access port (TAP).

8. The apparatus of claim 1, wherein the at least one SIB circuit includes a first switch to couple the test access interface to the TDR based on a state of the first SIB circuit access register.

9. The apparatus of claim 8, wherein the SIB circuit includes a second SIB circuit access register coupled between the first SIB circuit access register and the reset register to provide access to the TDR from the first switch.

10. The apparatus of claim 9, wherein the at least one SIB circuit includes a second switch to couple the first switch to the TDR based on a state of the second SIB circuit access register.

11. The apparatus of claim 1, wherein the test network is in conformance with an IEEE iJTAG standard.

12. An apparatus, comprising:
a test controller configured to be coupled with a test access interface of a test network in an integrated circuit (IC); and
a memory including instructions that when executed by the controller cause a test apparatus to:
write a first bit into a first SIB circuit access register to provide access to a test path with a test data register (TDR),
write a second bit into a reset register coupled to the first SIB access register and to the TDR to control the TDR to come out of a reset state.

13. The apparatus of claim 12, wherein the test apparatus is to write a third bit into the reset register prior to writing the second bit, the third bit to cause the TDR to go into the reset state.

14. The apparatus of claim 12, wherein the test apparatus is to write a third bit into a second SIB circuit access register to provide access to the TDR from the first circuit access register.

15. A computer system, comprising:
a processor apparatus including:
a test access interface for a test network in an integrated circuit (IC), and
at least one SIB (section insert bit) circuit coupled to the interface, the SIB circuit including: (i) a first SIB circuit access register to provide access to a test path including a test data register (TDR), and (ii) a reset register coupled to the first SIB access register and to the TDR to control a reset state of the TDR based on a value from the first SIB access register; and
a memory circuit coupled to the processor apparatus.

16. The apparatus of claim 15, wherein the SIB circuit includes a logic gate with a first input coupled to the reset register and a second input coupled to a power indicator node.

17. The apparatus of claim 16, wherein the logic gate includes an output coupled to the TDR to control the reset state of the TDR.

18. The apparatus of claim 16, wherein the logic gate is to perform a logical AND operation.

19. The apparatus of claim 15, wherein the SIB circuit includes a second SIB circuit access register coupled between the first SIB circuit access register and the reset register to provide access to the reset register.

20. The apparatus of claim 19, wherein the second SIB circuit access register is coupled between the first SIB circuit access register and the TDR to provide access to the TDR.
